(19) United States
(12) Patent Application Publication
(10) Pub. No.: US 2025/0112091 A1
(43) Pub. Date: Apr. 3, 2025

(54) SURFACE TREATMENT ENABLING SUPER-CONFORMAL METAL CAP PROFILE ON MIDDLE OF-LINE (MOL) SILICIDES

(71) Applicant: Applied Materials, Inc., Santa Clara, CA (US)

(72) Inventors: Jianqiu GUO, San Jose, CA (US); Dong WANG, Zhuhai (CN); Liqi WU, San Jose, CA (US); Yiyang WAN, Sunnyvale, CA (US); Shumao ZHANG, San Jose, CA (US); Qihao ZHU, Sunnyvale, CA (US); Weifeng YE, San Jose, CA (US); Jiang LU, Milpitas, CA (US); Shihchung CHEN, Cupertino, CA (US)

(21) Appl. No.: 18/899,407

(22) Filed: Sep. 27, 2024

Related U.S. Application Data
(60) Provisional application No. 63/542,050, filed on Oct. 2, 2023.

(51) Int. Cl. H01L 21/768; C23C 16/02; C23C 16/42; C23C 16/455; H01J 37/32; H01L 21/285; H01L 23/532

(52) U.S. Cl. CPC H01L 21/76889; C23C 16/0227; C23C 16/42; C23C 16/45553; H01L 21/28518; H01L 21/76877; H01L 23/53257; H01J 37/32091

(57) ABSTRACT

A contact structure includes a cavity comprising a device contact formed on a surface of a substrate, a bottom surface, and sidewalls. A metal silicide layer disposed over the surface of the device contact, the bottom surface, and the sidewalls of the cavity, and a treated surface formed over a portion of the metal silicide layer disposed over the sidewalls of the cavity.

### CROSS-REFERENCE TO RELATED APPLICATIONS

This application claims the benefit of U.S. Provisional Patent Application Ser. No. 63/542,050 filed Oct. 2, 2023 which is hereby incorporated by reference.

### BACKGROUND

### Field

Embodiments of the present invention generally relate to methods for forming low resistivity contacts within a semiconductor device.

### Description of the Related Art

Integrated circuits have evolved into complex devices that can include billions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., DRAM (dynamic random access memory)) and logic devices, including both planar and three-dimensional structures. Three-dimensional structures include fin field-effect transistor (finFET) or metal-oxide-semiconductor field-effect transistor (MOSFET) devices.

An example of finFET or MOSFET devices includes a gate electrode on a gate dielectric layer on a surface of a semiconductor substrate. Source/drain regions are provided along opposite sides of the gate electrode. The source and drain regions are generally heavily doped regions of the semiconductor substrate. Usually a metal silicide layer, for example a titanium silicide layer, is required to form a reliable contact at the formed source and drain regions.

In traditional middle-end-of-line (MEOL) contact formation, a plasma enhanced process is used to form a metal silicide layer, such as a titanium silicide (TiSi) layer on a silicon or silicon germanium connection as a capping layer.

Following the TiSi/TiSiN formation, the structure is filled with a low resistivity metal such as cobalt (Co), tungsten (W), or Molybdenum (Mo). For example, a physical vapor deposition process (PVD) process may be used to fill the structure from the bottom-up with a low resistivity metal, such as W. Then, the metal silicide layer and the PVD W formed on the field and the sidewall are removed by a pull-back process, and only the PVD W remains at the bottom of the structure. However, the remaining PVD W is slanted and it becomes challenging to deposit a continuous PVD W film over the sloped remaining PVD W. Therefore, to ensure good W coverage a low growth rate selective fluoride free tungsten (FFW) atomic layer deposition (ALD) process is used to deposit W over the slanted PVD W to partially fill of fully fill the structure.

However, these process steps lead to a contact structure with a high resistance at a high cost due to the expensive FFW ALD process and the etch pull-back process. Furthermore, as the size of structure decreases it is becoming more and more challenging to perform the pull-back process to remove the low resistivity metal formed on the field and the sidewall of the structure.

Thus, there is a need for improved methods to reduce contact resistance and simplified processes of contact formation.

### SUMMARY

According to one or more embodiments, a method includes depositing a metal silicide layer within a cavity of a contact structure, the cavity including a device contact formed on a surface of a substrate, a bottom surface, and sidewalls, wherein the metal silicide layer is deposited over a surface of the device contact, the bottom surface, and the sidewalls of the cavity, treating a portion of the metal silicide layer disposed over the sidewalls of the cavity using a treatment process, and conformally depositing a metal capping material over the surface of the device contact and the bottom surface via a metal fill capping process.

According to one or more embodiments, a contact structure includes a cavity comprising a device contact formed on a surface of a substrate, a bottom surface, and sidewalls, a metal silicide layer disposed over the surface of the device contact, the bottom surface, and the sidewalls of the cavity; and a treated surface formed over a portion of the metal silicide layer disposed over the sidewalls of the cavity.

According to one or more embodiments, a processing system includes a plurality of processing chambers, a controller, and a memory for storing instructions, which, when executed by the controller, causes the controller to perform a method in one or more of the plurality of processing chambers for forming a feature on a substrate, the method including depositing a metal silicide layer within a cavity of a contact structure, the cavity including a device contact formed on a surface of the substrate, a bottom surface, and sidewalls, wherein the metal silicide layer is deposited over a surface of the device contact, the bottom surface, and the sidewalls of the cavity, treating a portion of the metal silicide layer disposed over the sidewalls of the cavity using a treatment process, and conformally depositing a metal capping material over the surface of the device contact and the bottom surface via a metal fill capping process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a method for reducing contact resistance, in accordance with one or more embodiments.

FIGS. 2A, 2B, 2C, 2D, and 2E illustrate cross-sectional views of a portion of a semiconductor structure during the method of FIG. 1 for reducing contact resistance, in accordance with one or more embodiments.

FIGS. 3A, 3B, and 3C illustrate cross-sectional views of a portion of the semiconductor structure with different inhibition gradients, according to one or more embodiments.

FIG. 4 illustrates an integrated tool for use in performing the method of FIG. 1 in accordance with one or more embodiments.

FIG. 5 illustrates a graph illustrating differences in a deposition rate of a metal capping material during a metal fill capping process, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of the present disclosure provide contacts that have a reduced resistivity. The methods described herein can integrate multiple processes on the same integrated tool as well as achieve low contact resistance (Rc). For example, a treatment process is used to selectively passivate a metal silicide layer formed on sidewalls of structures to create an incubation delay for a subsequent in-situ molybdenum (Mo) or tungsten (W) metal fill/capping. The incubation delay allows for the metal capping to be super-conformal to the bottom surface of the structure, and thus, the metal capping layer has better coverage on the bottom surface of the structure versus the sidewalls. Advantageously, the incubation delay reduces metal capping material formed on the sidewall, and leaves a structure with a wider width for a subsequent pull-back process while still preventing the metal silicide layer on the sidewalls from oxidizing during subsequent process steps. Furthermore, the treatment process may eliminate the need to perform a physical vapor deposition process (PVD) process.

### Metal Capping and Treatment Process Sequence(s)

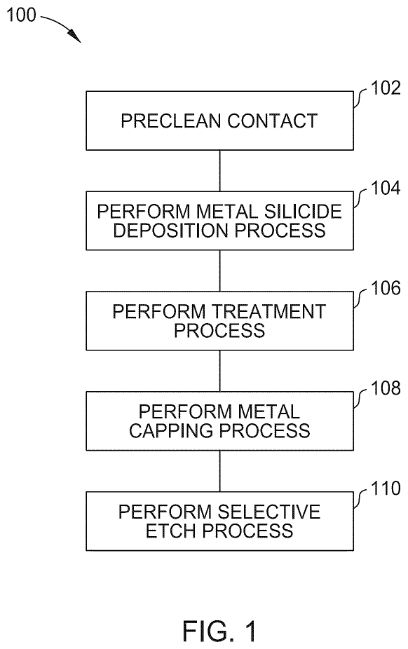

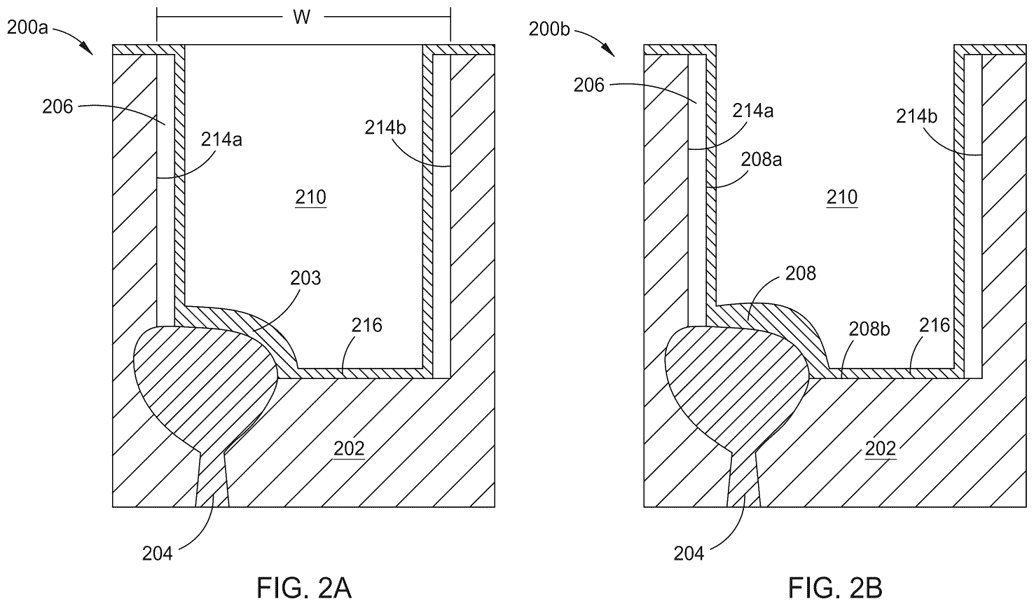

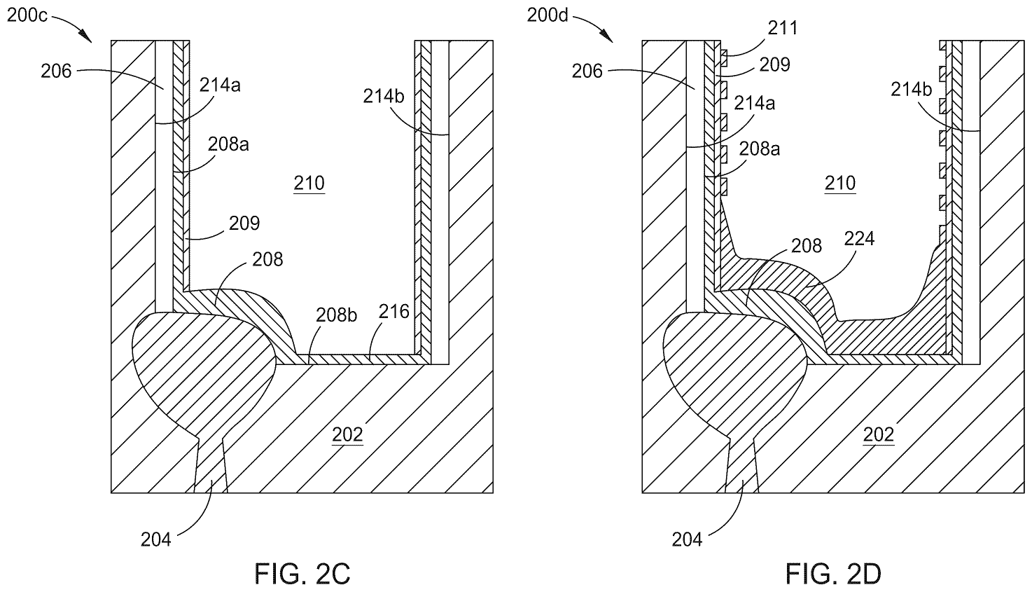

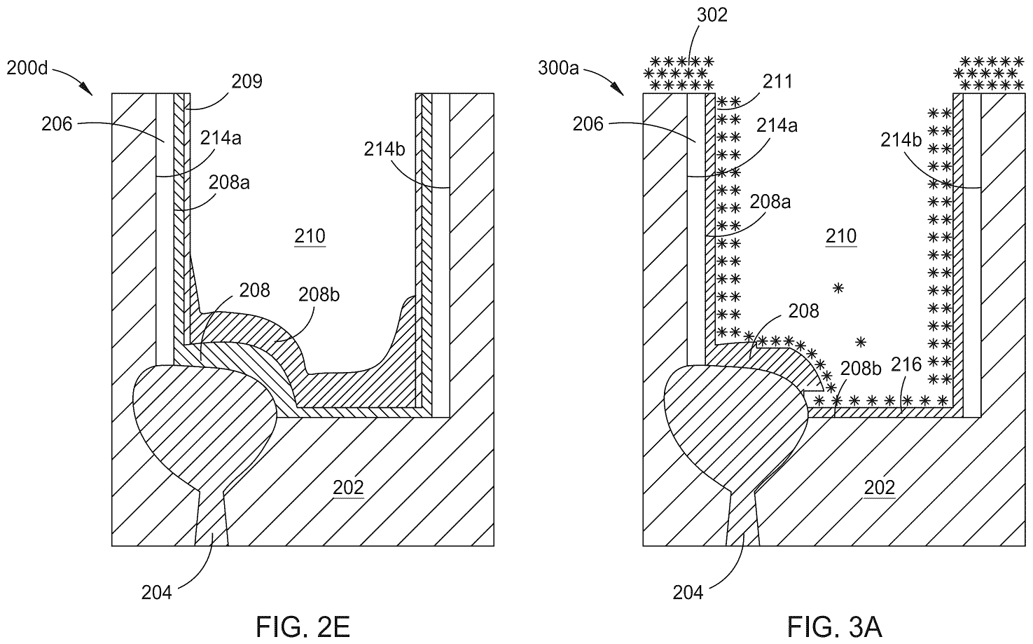

FIG. 1 illustrates a method 100 for reducing contact resistance, in accordance with one or more embodiments. FIGS. 2A-2E illustrate cross-sectional views of a portion of a semiconductor structure during the method 100 for reducing contact resistance, in accordance with one or more embodiments. In the discussion of the method 100, references will be made to the views 200A-200E of FIGS. 2A-2E.

At operation 102, a preclean process is performed to remove any contaminates and/or oxidation from surfaces of a contact structure as depicted in a view 200a of FIG. 2A. The contact structure has a silicon-based portion 204 (i.e., a device contact) that is exposed in a cavity 210 of a substrate 202 formed of a dielectric material (e.g., silicon dioxide, silicon nitride). In some examples, the silicon-based portion 204 is formed through a bottom surface 216 of the cavity 210. In some embodiments, the silicon-based portion 204 may be a silicon material or a silicon germanium (SiGe) material. In one or more examples, a dielectric layer 206 comprising a different material than the substrate 202 may be formed on sidewalls 214a and 214b of the cavity 210, and thus the cavity 210 is formed within a dielectric layer 206 that is disposed across the surface of the substrate 202. In another embodiment, the dielectric layer is not formed on sidewalls 214a and 214b of the cavity 210. In some embodiments, the dielectric layer 206 includes a low-k dielectric, silicon oxide, silicon nitride or other useful dielectric material. In one example, dielectric layer 206 contains a low-k dielectric material, such as a silicon carbide oxide material or a carbon doped silicon oxide material, for example, BLACK DIAMOND® II low-k dielectric material, available from Applied Materials, Inc., located in Santa Clara, California.

In one or more embodiments, cavities (e.g., vias), such as cavity 210 can have an average width W. For example, cavity 210 can have a width W (FIG. 2A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 210 can have an aspect ratio (depth:width) of about 1:1 to about 100:1, such as about 5:1, 10:1.

For example, as shown in the view 200a of FIG. 2A, the preclean process is performed to remove a native oxide material 203 formed on sidewalls 214a and 214b of the cavity 210 and on the surface of the silicon-based portion 204. In one or more examples, the preclean process may include exposing the substrate 202 to a reducing agent during a thermal process or a plasma process. Reducing agents that are useful during the pre-treatment process include hydrogen (e.g., H₂ or atomic-H), ammonia (NH₃), a hydrogen and ammonia mixture (H₂/NH₃), atomic-N, hydrazine (N₂H₄), alcohols (e.g., methanol, ethanol, or propanol), derivatives thereof, plasmas thereof, or combinations thereof. Substrate 202 may be exposed to a plasma formed in-situ or remotely during the preclean process. In some embodiments of operation 102, substrate 202 is exposed to a plasma preclean process to remove contaminants from the surfaces of the cavity 210. Substrate 202 may be positioned within a processing chamber, exposed to a reducing agent, and heated to a temperature within a range from about 100° C. to about 400° C., such as about 200° C. or about 250° C. In some embodiments, substrate 202 may be exposed to the plasma (e.g., in situ or remotely) for a time period within a range from about 2 seconds to about 60 seconds. The plasma may be produced at a power within the range from about 200 watts to about 1,000 watts, such as 350 watts.

In operation 104, a metal silicide deposition process is performed to produce a metal silicide layer 208 on the silicon-based portion 204 as depicted in view 200b of FIG. 2B. In one or more examples, the metal silicide layer 208 may comprise, titanium silicide (TiₓSi_{y}) which may include Ti₅Si₃, TiSi₂, TiSi, or combinations thereof. The metal silicide layer 208 is formed over the silicon-based portion 204, a bottom surface 216 of the cavity 210 and the dielectric layer 206. A portion 208a of the metal silicide layer 208 may be formed on the dielectric layer 206 and a portion 208b of the metal silicide layer 208 may be formed on the bottom surface 216 of the cavity 210. In one or more examples, the metal silicide layer 208 is deposited using a low selective direct plasma-enhance titanium (PE-TI) process. In other examples, the metal silicide layer 208 is deposited using a chemical vapor deposition (CVD) TiSi process. In examples in which the dielectric layer 206 is not formed on sidewalls 214a, 214b, the portion 208a of the metal silicide layer 208 may be formed directly onto the sidewalls 214a and 214b.

In operation 106, a treatment process is performed on the contact structure as depicted in view 200c of FIG. 2C. In one or more embodiments, the treatment process is used to passivate (cause nitridation of) the portion 208a of the metal silicide layer 208. In one or more embodiments, the treatment process includes exposing the contact structure to a plasma. In one or more embodiments, the treatment process is selective to the portion 208a of the metal silicide layer 208 (i.e., the portions of the metal silicide layer 208 that are not formed on the bottom surface 216 and the silicon-based portion 204). The treatment process treats the surface of the portion 208a. In other embodiments, the treatment process plasma is performed using a gradient nature so that only the portion 208a of the metal silicide layer 208 is exposed to the treatment process. The treatment process treats the portion 208a and forms a treated surface 209 on the portion 208a of the metal silicide layer 208. The treatment process includes passivating the portion 208a of the metal silicide layer 208 and creating an incubation delay (i.e., differences in incubation times) between the portion 208a (i.e., the treated surface 209), and the bottom surface 216 and the silicon-based portion 204 with respect to a subsequent metal fill capping process. In one or more embodiments, the treatment process is configured to only passivate the portion 208a of the metal silicide layer 208 so that the incubation delay allows for a metal capping material deposited during a subsequent metal fill capping process to grow on the bottom surface 216 and the silicon-based portion 204 at a faster rate than on the treated surface 209 (i.e., the portion 208a). Thus, the treatment process allows for a super-conformal metal fill capping process. This will be described in more detail below.

In one or more embodiments, the treatment process includes exposing the contact structure to a capacitively coupled plasma (CCP) formed from one or more treatment gases including, but not limited to, nitrogen (N₂), hydrogen (H₂), or combinations thereof. The plasma treatment process may be performed at a radio frequency (RF) from about 350 KHZ to about 27 MHz, for example 350 KHz, with a processing chamber temperature from about 400° C. to about 480° C., for example, 470° C., and a power from about 50 W to about 1000 W, for example 100 W. In one or more embodiments, the CCP plasma may be formed by flowing both nitrogen and hydrogen into the processing chamber. The flow rate of hydrogen may be from about 0 to about 8000 sccm, for example 6000 sccm, and the flow rate of nitrogen may be from about 1000 sccm to about 8000 sccm, for example 1000 sccm. The plasma treatment process may be performed for a treatment time of about 10 seconds to about 30 seconds, for example 20 seconds. The plasma treatment process may be performed with a chamber pressure from about 1 Torr to about 10 Torr, for example 4 T. The ability to perform the super-conformal metal fill capping process is due to the selectivity of the treatment process. Therefore, the process parameters of the treatment process, including, but not limited to, the treatment time, chamber pressure, and power can be adjusted so that the treatment process is selective to the portion 208a to generate an incubation delay between the treated surface 209 (i.e., the portion 208a) and the bottom surface 216 and the silicon-based portion 204. In one or more embodiments, a ratio of the treatment time of the treatment process to the power of the treatment process is from about 1:50 from 3:5.

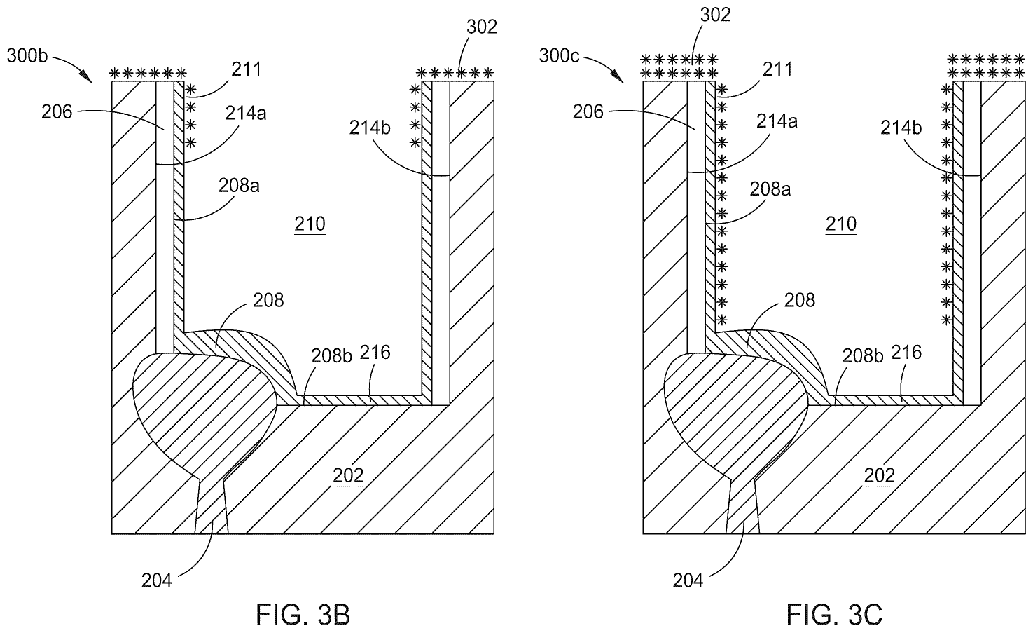

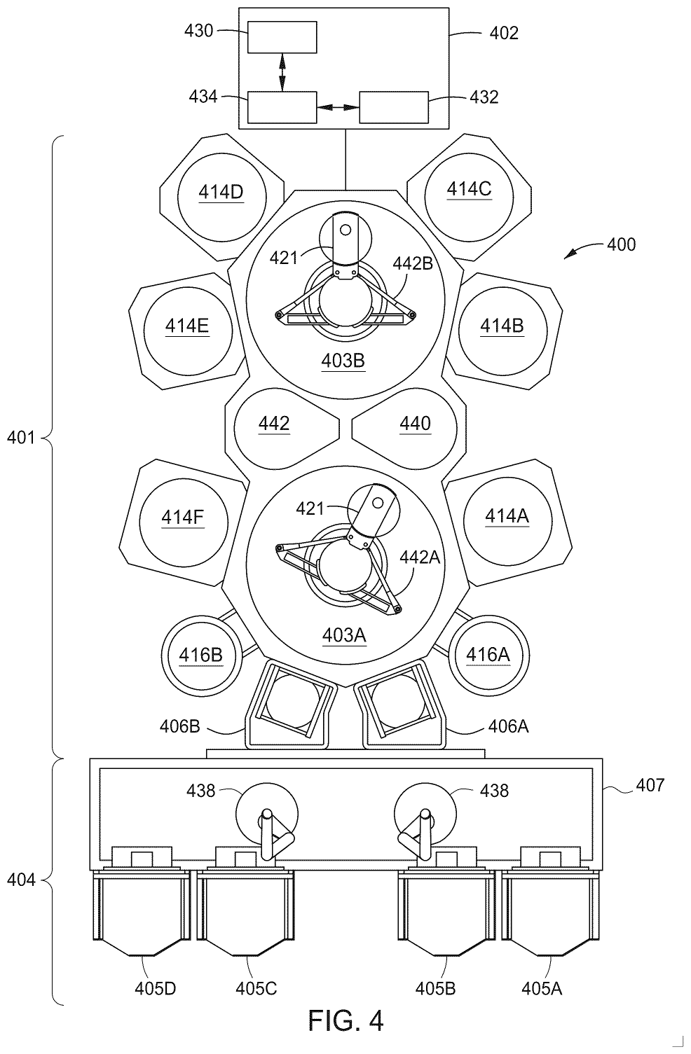

FIGS. 3A-3C illustrate cross-sectional views of a portion of the semiconductor structure with different inhibition gradients, according to one or more embodiments. Generally, diffusion of treatment radicals generated during the plasma treatment process into the cavity 210 is controlled, using the processes parameters of the treatment process to cause a desired inhibition gradient across the portion 208a of the metal silicide layer 208. In the view 300a shown in FIG. 3A, a CCP plasma that is too strong is generated during the treatment process. Due to the process parameters of the treatment process, treatment radicals 302 diffuse into the cavity 210 and are able to accelerate to reach the metal silicide layer 208 formed on the bottom surface 216 (i.e., portion 208b) and the silicon-based portion 204. Therefore, a CCP plasma that is too strong will also passivate the metal silicide layer 208 formed on the bottom surface 216 and the silicon-based portion 204. Due to the treatment of the entire metal silicide layer 208, a strong incubation delay will be present on both the sidewalls 214a and 214b, and the bottom surface 216 and there would be no selectivity in terms of metal capping profile within the cavity 210.

On the other hand, in the view 300b of FIG. 3B a CCP plasma that is too weak is generated during the treatment process. Because the CCP plasma is too weak, the treatment radicals 302 do not diffuse into the cavity 210 and the metal silicide layer 208 is not treated. Similarly, the incubation delay will not be present and there would be an equal growth of the metal capping material within the cavity 210.

In the view 300c of FIG. 3C (and view 200c of FIG. 2C), a CCP plasma that is selective to the portion 208a of the metal silicide layer 208 is generated. As shown in FIG. 3C, the process parameters of the treatment process are controlled so the inhibition effect increases the treatment radicals 302 on the portion 208a of the metal silicide layer 208 and prevents the treatment radicals 302 from reaching metal silicide layer 208 formed the bottom surface 216 and the silicon-based portion 204. As a result, the metal capping material to be formed within the cavity in a subsequent step is more easily established over the silicon-based portion 204 and the bottom surface 216, and once established, metal capping material growth accelerates from regions of the metal silicide layer 208 that have not be passivated to promote bottom-up growth of the metal material. Diffusion of the treatment radicals 302 into the cavity 210 typically depends, at least in part, on the size and aspect ratios of the cavity 210 and may be adjusted by controlling inter alia, the process parameters of the treatment process.

In operation 108, and as shown in the view 200d of FIG. 2D, a metal fill capping process may be used to deposit a metal capping material 224 within the cavity 210. In one or more embodiments, the metal capping material 224 includes, but is not limited to, tungsten (W). molybdenum (Mo), or cobalt (Co). In one or more embodiments, the metal fill capping process is a bottom-up metal fill capping process used to deposit the metal capping material 224 in the cavity 210 and over the metal silicide layer 208 formed over the bottom surface 216 and the silicon-based portion 204. As noted above, the metal fill capping process is super-conformal to the metal silicide layer 208 formed over the bottom surface 216 and the silicon-based portion 204 due to the passivation (i.e., the treated surface 209) of the portion 208a of the metal silicide layer 208.

The metal fill capping process may include exposing the contact structure to a metal precursor, such as a fluorine-free-tungsten (FFW) precursor, or a Mo precursor along with a suitable reducing agent, such as hydrogen (H₂). In one example, the metal precursor is a chlorine (CI) containing precursor. In one or more embodiments, the FFW precursor includes, but is not limited to, tungsten pentachloride (WCl₅) or tungsten hexachloride (WCl₆). In one or more embodiments the Mo precursor includes, but is not limited to, molybdenum pentachloride (MoCl₅).

In one or more embodiments, the metal fill capping process can be used to form a metal capping material 224 that functions as a thin metal cap to cover all junction silicide using either the fluorine-free-tungsten (FFW) precursor or the Mo precursor. The metal fill capping process can be an atomic layer deposition (ALD) process or a pulsed CVD bottom-up fill process (i.e., cycling a CVD process steps and purge steps). The metal fill capping process may be performed at a chamber pressure between about 10 T and about 300 T, for example about 20 T to 150 T. The metal fill capping process may include flowing the metal precursor at a flow rate in the presence of a reducing agent, such as hydrogen (H₂) or diborane (B₂H₆) and a carrier gas such as argon (or another noble gas). The flow rate of the reducing agent may be between about 1000 sccm and 20000 sccm. The carrier gas flow rate may be between about 100 sccm and about 2000 sccm, for example, 700 sccm. The metal fill capping process may be performed at a temperature of between about 350° C. and about 500° C., for example, from about 400° C. to about 400° C. In another embodiment, the metal fill capping process is a CVD process using a metal precursor and is used to fill the cavity 210 and a connected junction silicide to a metal network.

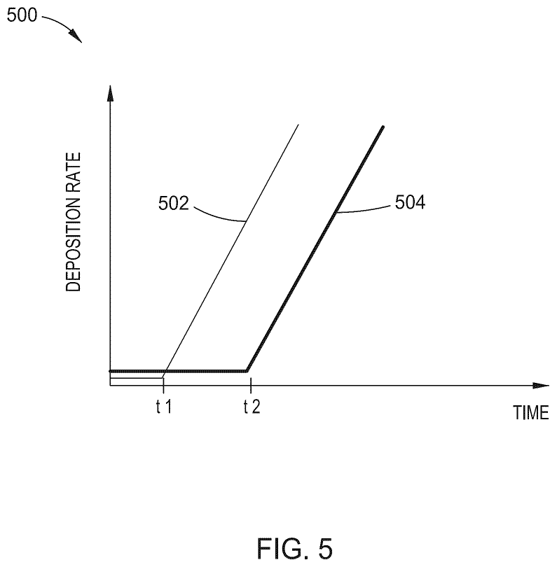

FIG. 5 illustrates a graph 500 illustrating the differences in the deposition rate of the metal capping material 224 during the metal fill capping process, according to one or more embodiments. Graph 500 shows the deposition rate of the metal capping material 224 formed on the portion 208a (i.e., the treated surface 209) of the metal silicide layer 208 versus the deposition rate of the metal capping material 224 formed over the metal silicide layer 208 formed over the bottom surface 216 and the silicon-based portion 204. As shown in FIG. 5, due to the treatment (passivation) of the portion 208a of the metal silicide layer 208, there is an incubation delay during the metal fill capping process between the portion 208a of the metal silicide layer 208 and the metal silicide layer 208 formed over the bottom surface 216 and the silicon-based portion 204. FIG. 5 illustrates a line 502 representing the metal capping material 224 deposition rate versus time over the bottom surface 216 and the silicon-based portion 204 and a line 504 representing the deposition rate of the metal capping material 224 over the portion 208a of the metal silicide layer 208. As shown in FIG. 5 the line 502 remains constant and then accelerates at a time t1. Stated otherwise, the metal silicide layer 208 (the untreated portions of the metal silicide layer 208) has an incubation time during the metal fill capping process between the start of the metal fill capping process (i.e., time equal zero) until the time t1. In one or more examples the time t1 is from about 0 to about 30 s. However, as noted above, due to the treatment (passivation) of the portion 208a, the treated surface 209 has an incubation time from the start of the metal fill capping process to a time t2 that occurs after the time t1. Thus, the line 504 does not begin to accelerate until the after the time t2. Therefore, there is an incubation delay equal to the time t2 minus the time t1. In one or more embodiments, the time t2 does not occur until after the time t1. The time t2 may be from about 250 s to about 850 s.

Thus, the treatment process generates an incubation delay for the growth of the metal capping material 224 between the treated surface 209 and the untreated portions of the metal silicide layer 208 (the bottom surface 216 and the silicon-based portion 204). Therefore, the differences in incubation times causes the metal fill capping process to be super-conformal to the bottom surface 216 and the silicon-based portion 204 if the metal fill capping process is performed for a duration of time greater than time t1, but less than time t2. Referring back to FIG. 2E, by performing the metal fill capping deposition process for a duration of time between the time t1 and the time t2, minimal amounts of residual metal capping material 211 (i.e., islands of the metal capping material 224) are formed on the portion 208a. Advantageously, the differences in incubation delays reduces the metal capping material 224 formed on the portion 208a (i.e., forms residual capping material 211). The residual capping material allows for a wider cavity width to be maintained for subsequent pull-back process while still protecting the portion 208a of the metal silicide layer 208 from oxidizing during subsequent process steps. Furthermore, the treatment process may eliminate the need to perform the physical vapor deposition process (PVD) process (i.e., only a single metal capping layer deposition is required).

At operation 110 a selective etch process is performed and is depicted in a view 200e of FIG. 2E. For example, a simple and low cost in-situ dry etch or wet etch process can remove the residual metal capping material 211, leaving the metal capping material 224 over the metal silicide layer 208 and the bottom surface 216. The etch process (operation 106) and the metal fill capping process (operation 108) may be performed in the same or different processing chambers.

In one or more embodiments, operations 108-110 are repeated until the metal capping material 224 reaches a desired thickness within the cavity 210 measured from the bottom surface 216. The desired thickness may be from about 5 to about 10 nm, for example about 7 nm.

### Processing System Examples

The methods of the present disclosure may be performed in individual process chambers that may be provided as part of a processing system, for example, an integrated tool 400 (e.g., cluster tool) described below with respect to FIG. 4. The advantage of using an integrated tool 400 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 400 includes a vacuum-tight processing platform 401, a factory interface 404, and a system controller 402. The processing platform 401 comprises multiple processing chambers, such as 414A, 414B, 414C, 414D, 414E, and 414F operatively coupled to a vacuum substrate transfer chamber (transfer chambers 403A, 403B). The factory interface 404 is operatively coupled to the transfer chamber 403A by one or more load lock chambers (two load lock chambers, such as 406A and 406B shown in FIG. 4).

In some embodiments, the factory interface 404 comprises at least one docking station 407, at least one factory interface robot 438 to facilitate the transfer of the semiconductor substrates. The docking station 407 is configured to accept one or more front opening unified pod (FOUP). Four FOUPS, such as 405A, 405B, 405C, and 405D are shown in the embodiment of FIG. 4. The factory interface robot 438 is configured to transfer the substrates from the factory interface 404 to the processing platform 401 through the load lock chambers, such as 406A and 406B. Each of the load lock chambers 406A and 406B have a first port coupled to the factory interface 404 and a second port coupled to the transfer chamber 403A. The load lock chamber 406A and 406B are coupled to a pressure control system (not shown) which pumps down and vents the load lock chambers 406A and 406B to facilitate passing the substrates between the vacuum environment of the transfer chamber 403A and the substantially ambient (e.g., atmospheric) environment of the factory interface 404. The transfer chambers 403A, 403B have vacuum robots 442A, 442B disposed in the respective transfer chambers 403A, 403B. The vacuum robot 442A is capable of transferring substrates 421 between the load lock chamber 406A, 406B, the processing chambers 414A and 414F and a cooldown station 440 or a pre-clean station 442. The vacuum robot 442B is capable of transferring substrates 421 between the cooldown station 440 or pre-clean station 442 and the processing chambers 414B, 414C, 414D, and 414E.

In some embodiments, the processing chambers 414A, 414B, 414C, 414D, 414E, and 414F are coupled to the transfer chambers 403A, 403B. The processing chambers 414A, 414B, 414C, 414D, 414E, and 414F may comprise, for example, preclean chambers, ALD process chambers, PVD process chambers, remote plasma chambers, CVD chambers, or the like. The chambers may include any chambers suitable to perform all or portions of the methods of the present disclosure, as discussed above, such as PVD W or PVD Mo chambers, CVD chambers, ALD chambers and the like. In some embodiments, one or more optional service chambers (shown as 416A and 416B) may be coupled to the transfer chamber 403A. The service chambers 416A and 416B may be configured to perform other substrate processes, such as degassing, orientation, substrate metrology, cool down, and the like.

The processing chambers 420, 422, 424, 426, 428 may be any appropriate chamber for processing a substrate. In some examples, a processing chamber may be capable of performing an etch process, a cleaning process, an annealing process, a CVD deposition process, or an ALD deposition processes. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

The system controller 402 controls the operation of the tool 400 using a direct control of the process chambers 414A, 414B, 414C, 414D, 414E, and 414F or alternatively, by controlling the computers (or controllers) associated with the process chambers 414A, 414B, 414C, 414D, 414E, and 414F and the tool 400. In operation, the system controller 402 enables data collection and feedback from the respective chambers and systems to optimize performance of the tool 400. The system controller 402 generally includes a Central Processing Unit (CPU) 430, a memory 434, and a support circuit 432. The CPU 430 may be any form of a general-purpose computer processor that can be used in an industrial setting. The support circuit 432 is conventionally coupled to the CPU 430 and may comprise a cache, clock circuits, input/output subsystems, power supplies, and the like. Software routines, such as a method as described above may be stored in the memory 434 and, when executed by the CPU 430, transform the CPU 430 into a specific purpose computer (system controller) 402. The software routines may also be stored and/or executed by a second controller (not shown) that is located remotely from the tool 400.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

While the foregoing is directed to embodiments of the present principles, other and further embodiments of the principles may be devised without departing from the basic scope thereof.

What is claimed is:

1. A method, comprising:
depositing a metal silicide layer within a cavity of a contact structure, the cavity including a device contact formed on a surface of a substrate, a bottom surface, and sidewalls, wherein the metal silicide layer is deposited over a surface of the device contact, the bottom surface, and the sidewalls of the cavity;
treating a portion of the metal silicide layer disposed over the sidewalls of the cavity using a treatment process; and
conformally depositing a metal capping material over the surface of the device contact and the bottom surface via a metal fill capping process.

2. The method of claim 1, further comprising performing a selective etch process to remove a residual metal capping material formed on the sidewalls of the cavity.

3. The method of claim 2, further comprising repeating the conformally depositing the metal capping material over the surface of the device contact and the bottom surface and the performing the selective etch process to remove the residual metal capping material formed on the sidewalls of the cavity until the metal capping material reaches a desired thickness.

4. The method of claim 1, wherein the treatment process comprises generating a capacitively coupled plasma (CCP) formed from one or more treatment gases.

5. The method of claim 4, wherein the one or more treatment gases include nitrogen (N2), hydrogen (H2), or combinations thereof.

6. The method of claim 1, wherein the conformally depositing a metal capping material comprises exposing the contact structure to a fluorine-free-tungsten (FFW) precursor, or a molybdenum (Mo) precursor.

7. The method of claim 6, wherein the FFW precursor comprises tungsten pentachloride (WCl₅) or tungsten hexachloride (WCl₆).

8. The method of claim 1, wherein the metal capping material comprises tungsten (W) or molybdenum (Mo).

9. The method of claim 1, further comprising performing a pre-treatment process on the contact structure to remove a native oxide material disposed within the cavity prior to depositing the metal silicide layer.

10. A contact structure, comprising:
a cavity comprising a device contact formed on a surface of a substrate, a bottom surface, and sidewalls;
a metal silicide layer disposed over the surface of the device contact, the bottom surface, and the sidewalls of the cavity; and
a treated surface formed over a portion of the metal silicide layer disposed over the sidewalls of the cavity.

11. The contact structure of claim 10, further comprising a metal capping material disposed within the cavity.

12. The contact structure of claim 11, wherein the metal capping material comprises tungsten (W) or molybdenum (Mo).

13. A processing system, comprising:
a plurality of processing chambers;
a controller; and
a memory for storing instructions, which, when executed by the controller, causes the controller to perform a method in one or more of the plurality of processing chambers for forming a feature on a substrate, the method comprising:
depositing a metal silicide layer within a cavity of a contact structure, the cavity including a device contact formed on a surface of the substrate, a bottom surface, and sidewalls, wherein the metal silicide layer is deposited over a surface of the device contact, the bottom surface, and the sidewalls of the cavity;
treating a portion of the metal silicide layer disposed over the sidewalls of the cavity using a treatment process; and
conformally depositing a metal capping material over the surface of the device contact and the bottom surface via a metal fill capping process.

14. The processing system of claim 13, wherein the method further comprises performing a selective etch process to remove residual metal capping material formed on the sidewalls of the cavity.

15. The processing system of claim 14, wherein the method further comprises repeating the conformally depositing the metal capping material over the surface of the device contact and the bottom surface and the performing the selective etch process to remove the residual metal capping material formed on the sidewalls of the cavity until the metal capping material reaches a desired thickness.

16. The processing system of claim 13, wherein the treatment process comprises generating a capacitively coupled plasma (CCP) formed from one or more treatment gases.

17. The processing system of claim 16, wherein the one or more treatment gases comprise nitrogen (N₂), hydrogen (H₂), or combinations thereof.

18. The processing system of claim 13, wherein the conformally depositing the metal capping material comprises exposing the contact structure to a fluorine-free-tungsten (FFW) precursor, or a molybdenum (Mo) precursor.

19. The processing system of claim 18, wherein the FFW precursor comprises tungsten pentachloride (WCl₅) or tungsten hexachloride (WCl₆).

20. The processing system of claim 13, wherein the method further comprises performing a pre-treatment process on the contact structure to remove a native oxide material disposed within the cavity prior to depositing the metal silicide layer.
